(19) United States
(12) Patent Application Publication
(10) Pub. No.: US 2010/0141257 A1
(43) Pub. Date: Jun. 10, 2010

(54) RF TRANSMITTER WITH DIGITAL FEEDBACK FOR MRI

(75) Inventors: Ingmar Graesslin, Boenningstedt (DE); Peter Vernickel, Hamburg (DE); Johannes Hendrik Den Boef, Eindhoven (NL)

Correspondence Address: PHILIPS INTELLECTUAL PROPERTY & STANDARDS, P. O. Box 3001, BRIARCLIFF MANOR, NY, 10510, US

(73) Assignee: KONINKLIJKE PHILIPS ELECTRONICS N.V., EINDHOVEN (NL)

(21) Appl. No.: 12/598,454

(22) PCT Filed: Apr. 3, 2008
(86) PCT No.: PCT/IB2008/051253

§ 371 Date: Nov. 2, 2009

(30) Foreign Application Priority Data
May 4, 2007 (EP) 07107532.9

(51) Int. Cl. G01R 33/44

(52) U.S. Cl. 324/314

(57) ABSTRACT

A method and an RF transmit system for generating RF transmit signals for feeding an RF transmitter (14) in the form of, or comprising, one or more antenna device(s), coil(s), coil elements, or coil array(s) is disclosed. Furthermore, a multi-channel RF transmit system for feeding a plurality of such RF transmitters, especially for use as an RF excitation system in a magnetic resonance imaging (MRI) system for exciting nuclear magnetic resonances (NMR) is disclosed. A demand RF transmit signal is compared in the digital domain with an RF transmit signal and digitally corrected with respect to differences or errors between both by means of a complex predistorter (11), an adaption unit (17) and a look-up table unit (18).

### FIELD OF INVENTION

The invention relates to a method and an RF transmit system for generating RF transmit signals for feeding an RF transmitter in the form of, or comprising, one or more antenna device(s), coil(s), coil elements, or coil array(s). Furthermore, the invention relates to a multi-channel RF transmit system for feeding a plurality of such RF transmitters, especially for use as an RF excitation system in a magnetic resonance imaging (MRI) system for exciting nuclear magnetic resonances (NMR). The invention further relates to an MRI system comprising such a one- or multi-channel RF transmit or excitation system.

### BACKGROUND OF THE INVENTION

WO 2005/083458 discloses a “method of effecting nuclear magnetic resonance experiments using Cartesian feedback”, and a particular arrangement with a plurality of transmitting coils, wherein each transmitting coil having its own independent transmitter and current detector for setting the amplitude and phase of its current to its required value. The deleterious effects of coupling between the coils shall be overcome or at least ameliorated by measuring the current in the coils and comparing the transmitter's known value of signal input with the values of the amplitude and phase of the measured current to determine a difference between these values, and using this difference to reset the amplitude and phase of the transmit signal input such that the amplitude and phase of the current in the coil is to high accuracy equal to the required value.

### SUMMARY OF THE INVENTION

It has revealed, that a disadvantage of the above method and arrangement is that instabilities of the feedback loop can occur under certain circumstances and load conditions, and that the expense for the circuitry increases rapidly with an increasing number of transmitting coils to be controlled. Furthermore, due to noise and component tolerances, with such a feedback loop only a limited accuracy of the desired amplitude and phase of the transmit signals can be obtained.

More in detail, it has revealed that the gain of an RF power amplifier included in the RF transmit system can be time dependent and can change during a transmitted RF pulse due to thermal heating of the components of the amplifier and due to amplifier power supply variations. These variations cause RF pulse output changes commonly known as pulse overshoot and drop. The gain of the power amplifier can also change from RF pulse to RF pulse, again due to other thermal and power supply conditions. These effects cause that the RF field generated may deviate from the desired RF field because the required time response of the RF power amplifier cannot be obtained, so that generally the level stability of the RF transmit signal is considered as a first problem to be addressed.

Furthermore, most RF power amplifiers have a significant non-linear response especially for higher output levels, so that the linearity of the RF transmit signal is a second problem to be addressed.

A third problem to be addressed is the dynamic range of the output signal of certain amplifiers especially in case of generating a mixed sequence of long low power and short high power RF pulses. This has the consequence that usually power supply conditions have to be changed in order to accommodate the required RF pulse.

In case of a magnetic resonance imaging (MRI) system these problems may result in degraded MR signal performance, so that poor image and spectral quality is observed. Especially by RF transmit level instabilities ghosting may occur, and by the RF transmit non-linearities, spatial resolution loss is observed.

All these problems are intensified or aggravated in case of a multi-channel RF transmit system for operating a plurality of RF transmitters in the form of, or comprising, a plurality of RF coils or coil arrays, or in case of other multi-channel RF excitation systems, as they are used for example in MRI systems. Due to the usual close alignment between the RF transmit channels, and in-dependence on the actual load of the related RF transmitters, mutual coupling effects between the individual transmit channels and their components occur, so that the phases and amplitudes of the signals in the RF transmit channels are not independent from each other and in turn power is exchanged between the individual RF transmit channels or elements. By this, the amplitude and/or phase of an RF signal at the output of one or more of the RF transmit channels (i.e. at the input of the RF transmitters) can deviate considerably from or vary in relation to a demanded amplitude and/or phase of a signal which is applied at the input of the related RF transmit channel, so that the RF field generated in an examination space of the MRI system may accordingly deviate from the desired RF field.

This causes problems especially in those MRI systems with higher magnetic field strengths in which the wavelengths of the required RF transmit or excitation signals reach the dimensions of an examination object which results in dielectric resonances or wave propagation effects within the examination object and inhomogeneous RF excitation fields. In order to compensate the impact of these unwanted effects during MRI examinations, especially the amplitudes and phases of the RF transmit signals of each of the RF transmit channels have to be selected and controlled independently from each other, for example by parallel transmit imaging or parallel transmission of RF pulses and according to known methods like Transmit SENSE (see e.g. Katscher et al, “Trannsmit SENSE” in Magnetic Resonances in Medicine (2003) 49: 144-150) or RF shimming (see Ibrahim et al, “Effect of RF coil excitation on field inhomogeneity at ultra high fields: a field optimized TEM resonator” in Magnetic Resonance Imaging (2001) December; 19(10): 1339-47).

Consequently, it is a basic requirement that the RF transmit signals at the transmitting coil elements of such an RF transmit system correlate as exactly as possible with the related demand signals which are calculated by the above methods of parallel transmit imaging.

One object underlying the invention is to provide a method and a one- or multi-channel RF transmit system for generating RF transmit signals for feeding one or a plurality of RF transmitters in the form of, or comprising, one or more antenna device(s), coil(s) or coil array(s) such that the RF transmit signals which are generated at the output of the at least one RF transmit channel correlate with or coincide with or match or correspond at least substantially and to a high accuracy with a demanded signal which is supplied to each channel of the RF transmit system or generated by the RF transmit system.

The above correlation or coincidence or correspondence is especially related to at least one of the amplitude, the phase, the level stability, the linearity and the dynamic range of the RF transmit signal in relation to the demand signal.

The extent of the above correlation or coincidence or correspondence is especially to be improved in comparison to the prior art as disclosed e.g. in the above WO 2005/083458.

The object is solved by a method according to claim 1 and an RF transmit system according to claim 3.

One advantage of the method and RF transmit system according to the invention is that by the realization in the digital domain, instabilities of the feedback loop can be avoided in a relatively easy and reliable manner even under detrimental or changing load conditions, if e.g. in case of an MRI system, an examination object is moved within the examination space which is exposed to the RF excitation field. In particular, also changes are taken into account of the load condition that are caused by motion of the patient such as breathing motion.

The safety margin can be reduced significantly, if a real-time feedback loop is used to change the input signal of the RF amplifier accordingly with the desired RF demand or in case current sources would be used. Therefore, during the scan, the deviation from the desired waveform is monitored to detect violations of the SAR limits or any unsafe conditions. The selection of an appropriate safety margin is a trade off between robust detection and associated larger “SAR margins” or smaller “SAR margins”, which result in a higher susceptibility/sensitive to patient movements. According the present invention, the real-time feedback loop is able to account for patient movements so that the SAR safety margin can by narrow while inadvertent terminations of the scan due to patient movement is avoided.

Furthermore, especially in case of a great number of RF transmit channels, the RF transmit system according to the invention requires less expense for the circuitry than in case of a realization in the analog domain.

The same applies for the influence of noise and tolerances of the components of the RF transmit system on the above correlation or correspondence which influence is considerably decreased or removed in comparison to a realization in the analog domain. Finally, in case of the application in an MRI system, the method and RF transmit system according to the invention can advantageously be combined with known methods for calculating amplitudes and phases of RF transmit or excitation signals for each of a plurality of RF transmit channels in order to obtain a desired (homogeneous) RF excitation field in an examination space, like e.g. RF shimming or Transmit SENSE methods.

The subclaims disclose advantageous embodiments of the invention.

The method according to claim 2 discloses preferred kinds of differences or errors between the detected RF transmit signal and the demand RF signal which are evaluated and compensated.

With the RF transmit systems according to claims 4 and 5, a very fast evaluation of the required correction of the demand RF signals in real-time and with a high accuracy can be conducted.

With the RF transmit system according to claim 6, the signal processing and correction can be conducted in a lower base frequency band.

It will be appreciated that features of the invention are susceptible to being combined in any combination without departing from the scope of the invention as defined by the accompanying claims.

Further details, features and advantages of the invention will become apparent from the following description of preferred and exemplary embodiments of the invention, which are given with reference to the drawings.

### BRIEF DESCRIPTION OF THE DRAWINGS

FIG. 1 shows an overall functional block diagram of an RF transmit system according to a first embodiment of invention;

FIG. 2 shows a detailed functional block diagram of a magnitude stabilizer of the RF transmit system according to FIG. 1;

FIG. 3 shows a detailed functional block diagram of a complex-to-polar converter of the RF transmit system according to FIG. 1;

FIG. 4 shows a functional block diagram of an RF transmit system according to a second embodiment of the invention; and

FIG. 5 shows a functional block diagram of an RF transmit system according to a third embodiment of the invention.

### DETAILED DESCRIPTION OF EMBODIMENTS

Generally, according to the invention, an RF transmit signal which is generated at the output of an RF transmit system or detected at the RF antenna (RF transmitter) is converted into the digital domain and compared in the digital domain with the original requested digital demand signal which is supplied to or generated by the RF transmit system. The digital error signal is used to correct the digital or analog input signal in order to obtain at the output of the RF transmit system (i.e. at the input of the RF antenna) the demand RF transmit output signal, so that a real-time feedback loop in the digital domain is realized.

In addition, a calibrated pre-compensation can be used to further increase the performance.

The embodiments of the RF transmit systems according to the invention which are explained in the following are especially provided for use as an RF excitation system in a magnetic resonance imaging system to generate an RF excitation field by means of an RF transmitter in the form of an RF coil within the examination zone of the MRI system. Usually, such RF excitation systems comprise a plurality of RF transmit systems (multi-channel RF excitation system), each in the form as described in the following.

According to a first embodiment of the invention, the RF transmit system generally comprises an RF power amplifier for feeding an RF transmitter with an RF signal, an activation circuit to provide an input signal to the RF power amplifier, and a control circuit to control the activation circuit. The control circuit samples the output signal of the RF power amplifier (or of the RF transmitter), digitally compares the measured output signal with a prescribed demand signal and digitally corrects the input or demand signal to the RF power amplifier.

According to a preferred variation of this first embodiment, the control circuit has a feedforward function, which presets the activation circuit on the basis of a selected MRI acquisition sequence.

By the first embodiment, especially an improved transmit level stability and linearity can be achieved. Furthermore, wider variations of the RF power level can be achieved by advance setting to the amplification level of the RF power amplifier. By the control circuit, a sampling of the output signal and a correction of the input signal within a time interval (typically 0.8 μs for sampling, 50 μs for correcting) that is less than the typical time of variation of the RF transmit level or less than the repetition rate of the RF pulses in the MRI acquisition sequence can be obtained. Even a correction of the setting of the RF amplifier may be performed within an RF pulse.

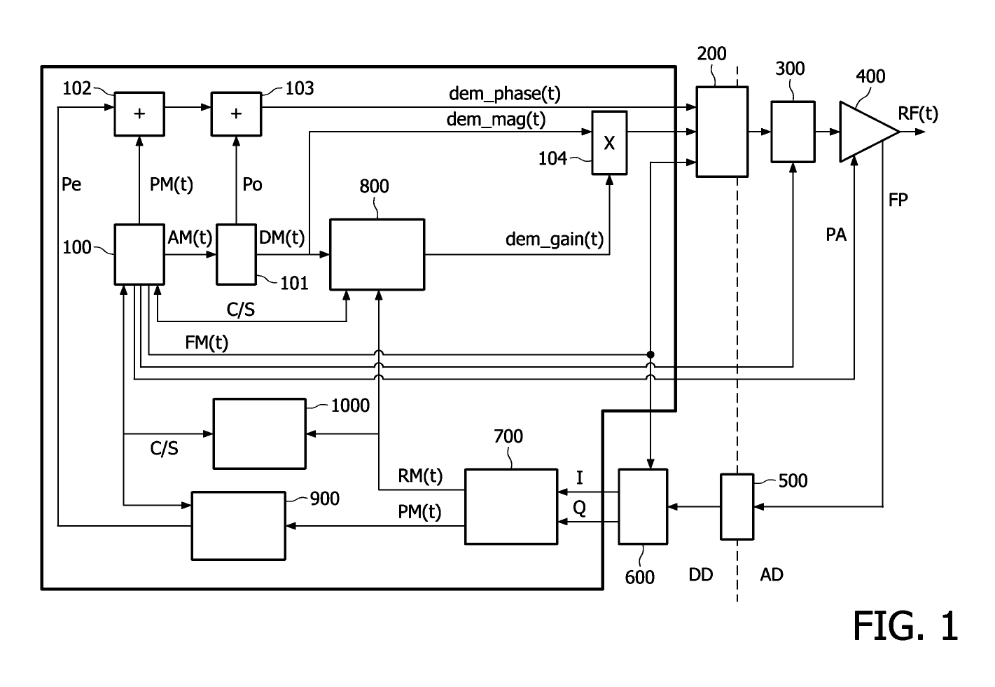

FIG. 1 shows an overall functional block diagram of such an RF transmit system according to the first embodiment of invention. It comprises a stretch engine 100, a magnitude function unit 101, a first adder unit 102 and a second adder unit 103, a multiplier 104, a direct digital synthesizer 200, an attenuator 300, an RF power amplifier 400, an analog-to-digital converter 500 between an analog domain AD and a digital domain DD, a digital receiver 600, a complex-to-polar converter 700, a magnitude stabilizer 800, a phase stabilizer 900 and a power monitoring unit 1000. The RF power amplifier 400 generates the output signal RF(t) for feeding an RF coil or antenna and comprises an enable input PA and an output FP for the forward power.

The stretch engine 100 acts as an interface between a software running on a computer and the real-time control MR hardware. The software determines the necessary hardware control settings for the next period of time (stretch) while the stretch engine 100 controls the hardware for the current stretch. So in each stretch the stretch engine 100 time controls the hardware with the settings preloaded by the software.

Amongst these settings are the requested or demanded settings for the RF pulse RF(t) (output pulse or RF transmit signal to be fed to the RF antenna) like magnitude, phase and carrier frequency. These settings are normally set every few microseconds to allow generation of the RF pulses RF(t) with a desired spectral response. The direct digital synthesizer 200 comprises three real-time controllable inputs, namely a first input for the magnitude of the RF pulse RF(t), a second input for the phase of the RF pulse RF(t) and a third input for the carrier frequency of the RF pulse RF(t).

The stretch engine 100 outputs every few microseconds samples of the requested or demanded amplitude waveform AM(t), the requested or demanded phase waveform PM(t) and the requested or demanded carrier frequency waveform FM(t). The amplitude samples AM(t) are converted by the magnitude function unit 101 to a magnitude sample DM(t) and a phase offset value Po. The phase offset value Po is 180° for negative amplitude samples and 0° for others.

The first adder unit 102 generates an output signal which is the sum of the requested or demanded phase waveform sample PM(t) generated by the stretch engine 100 and a phase error signal Pe generated by the phase stabilizer 900.

The second adder unit 103 adds the phase offset value Po to the output signal of the first adder unit 102 and generates the sum output signal (demanded or requested phase signal dem_phase(t)) to a first input of the direct digital synthesizer 200.

The requested or demanded magnitude sample signals dem_mag(t) (or DM(t)) are applied to a first input of the multiplier 104 and to the magnitude stabilizer 800 which by means of its output signal for gain of requested magnitude dem_gain(t) controls the second input of the multiplier 104, allowing control of the requested or demanded magnitude level applied to the second input (magnitude input) of the direct digital synthesizer 200.

The requested or demanded carrier frequency sample signals FM(t) are applied to the third input of the direct digital synthesizer 200 and to the digital receiver 600.

The RF output signal of the direct digital synthesizer 200 is applied to the input of the attenuator 300 which is used for coarse level setting of the desired RF transmit signal RF(t) by means of the stretch engine 100.

The output signal of the attenuator 300 is supplied to the RF power amplifier 400 for generating the RF transmit signal RF(t) to be fed to the RF antenna. The RF power amplifier 400 is enabled by an enable signal PA generated by the stretch engine 100. The forward power FP at the output of the RF power amplifier 400 is fed to the analog-to-digital converter 500, the output of which is connected with the digital receiver 600 for generating complex base-band signals I and Q which are supplied to the complex-to-polar converter 700 for generating a received magnitude signal RM(t) which is supplied to the magnitude stabilizer 800 and to the power monitoring unit 1000, and a received phase signal PM(t) which is supplied to the phase stabilizer 900.

The magnitude stabilizer 800, the phase stabilizer 900 and the power monitor unit 1000 are controlled by the stretch engine 100 via a C/S interface.

A fine level setting can also be conducted by controlling the magnitude stabilizer 800.

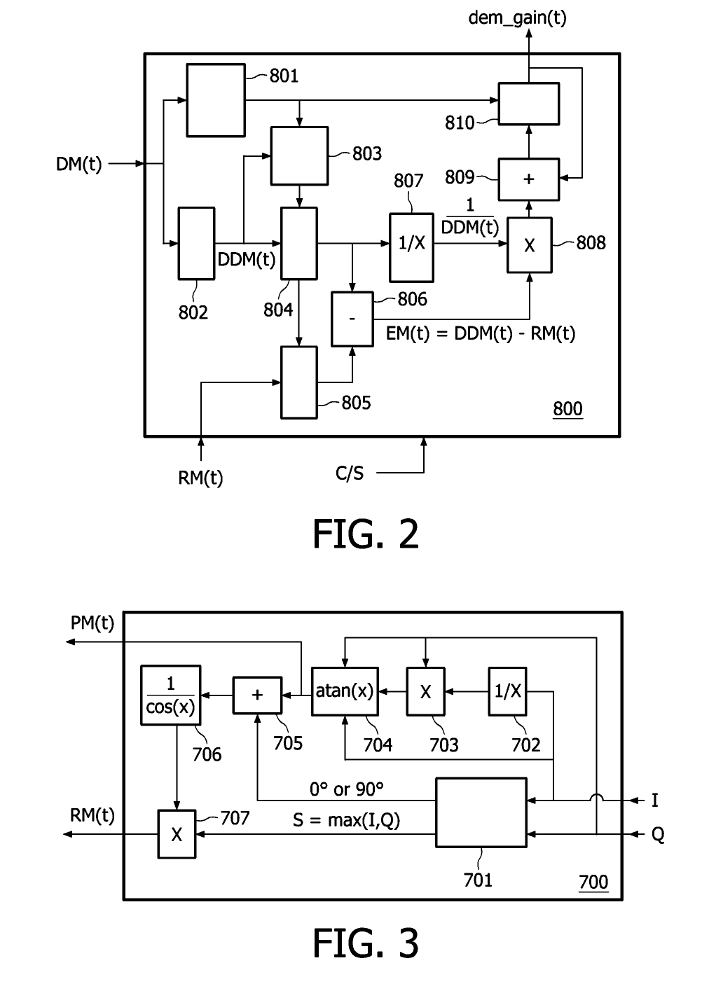

FIG. 2 shows a detailed functional block diagram of this magnitude stabilizer 800 of the circuit arrangement according to FIG. 1. It comprises a pulse start detect function unit 801, a delay function unit 802, a delay clock unit 803, a first latch unit 804 and a second latch unit 805, a subtracter unit 806, an inverse function unit 807, a multiplier 808, an adder unit 809 and a demand gain function unit 810.

The magnitude stabilizer 800 has four interfaces namely each one for the demand magnitude sample inputs DM(t), the received magnitude sample inputs RM(t), the demand gain output signal dem_gain(t) and a stretch engine interface C/S.

The magnitude stabilizer 800 is provided for comparing the received signal magnitude RM(t) with a delayed demand signal magnitude DDM(t), generated by means of the delay function unit 802. The difference EM(t) between these two signals DDM(t)−RM(t), generated by means of the subtracter unit 806, is multiplied by means of the multiplier 808 with a factor that is proportional to the inverse 1/DDM(t) of the delayed demand signal magnitude and added by means of the adder unit 809 to the previously used demand gain value dem_gain(t).

FIG. 3 shows a detailed functional block diagram of the complex-to-polar converter 700 of the circuit arrangement according to FIG. 1. It comprises a first functional unit 701 for receiving the complex base-band signals I and Q from the digital receiver 600, and for generating at a first output a signal S=max(I,Q) and at a second output a phase signal 0° or 90°. Furthermore, an inverse function unit 702, a first multiplier 703, a second functional a tan(x) unit 704, an adder unit 705, a third functional 1/cos(x) unit 706 and a second multiplier 707 are provided for generating the received magnitude signal RM(t) and a received phase signal PM(t).

The operation of the RF transmit system shown in FIGS. 1 to 3 shall now be explained in more details.

The output signal RF(t) of the power amplifier 400 is given by:

RF(t)=dem_mag(t)*dem_gain(t)*Gtx(t)*sin(ωt+φ)

where:
dem_mag(t)=requested magnitude of the RF signal as a function of time
dem_gain(t)=gain of requested magnitude as a function of time
Gtx(t)=gain of transmit part (i.e. output of multiplier 104 to output of power amplifier 400) as a function of time=
ω=carrier frequency of the RF signal;
φ=offset phase of the RF signal.

Normal cost effective RF power amplifiers tend to have gain variations within a pulse like for example pulse overshoot and pulse drop as well as gain variations over pulses and time. These are the main reasons for the time dependency of the transmit part gain Gtx(t). Assuming that the transmit part gain variations are relatively slow with respect to the rate with which one can update the gain of the requested magnitude, one can reduce the influence of these transmit part gain variations significantly. Transmit gain variations can be reduced by varying the demand magnitude gain dem_gain(t) such that the product of the two remains constant, i.e.:

dem_gain(t)*Gtx(t)=const.

This leads to the following desired relation for the variations of these two signals:

dGtx(t)=−[ddem_gain(t)/dem_gain(t)]*Gtx

The output signal of the power amplifier 400 is measured by receiving the forward power FP monitor output signal of the power amplifier 400. It is also possible to measure another RF signal further in the transmit chain like for example the RF signal of an RF field sensor coil positioned in the transmit coil or antenna.

This RF “monitor” signal is digitized by the analog-to-digital converter 500 and converted to complex base-band signals I and Q by the digital receiver 600. The base-band signals are converted to magnitude RM(t) and phase signals PM(t) by the complex-to-polar converter 700. The relation between the received magnitude RM(t) and the RF output signal RF(t) is given by:

RM(t)=Grx(t)*RF(t)=dem_mag(t)*dem_gain(t)*Gtx(t)*Grx(t)

where:
Grx(t)=gain of received magnitude signal RM(t) with respect to the generated RF signal RF(t) as a function of time.

It is hereby assumed, which is not unreasonable, that the variations in gain of the analog part of the received forward power are insignificant compared to the variations of the transmit part. This means that a constant receiver gain Grx can be assumed. The sensitivity of variations in the received magnitude signal RM(t) due to variations of the transmit gain Gtx(t) is given by:

dRM(t)/dGtx(t)=dem_mag(t)*dem_gain(t)*Grx

The delay function unit 802 delays the demand magnitude signal DM(t) such that it is synchronized in time with the received magnitude signal RM(t). This delay is equal to the propagation delay of the received magnitude signal RM(t) with respect to the magnitude demand signal DM(t). The delay can be in the order of microseconds.

The delay clock unit 803 produces a clock signal with a period time approximately equal to this delay plus the time needed to update the demand gain control signal. The delay clock unit 803 is inactive when the delayed demand signal DDM(t) has a signal level below a programmable threshold level.

On each clock pulse of the delay clock unit 803 the current values of the delayed demand magnitude signals DDM(t) and the received magnitude signals RM(t) are latched into the first and the second latch unit 804, 805, respectively.

The latched received magnitude signal RM(t) is subtracted from the latched delayed demand magnitude signal DDM(t) by the subtracter unit 806. Once stabilized, this difference signal EM(t) will be nearly zero. Any variation in the latched received magnitude signal RM(t) due to variations of the transmit gain are, with inverse sign, also present in the difference signal EM(t). So, the sensitivity of variations in the difference signal EM(t) due to variations of the transmit gain Gtx(t) is given by:

dEM(t)/dGtx(t)=−dem_mag(t)*dem_gain(t)*Grx

A combination with the equation dGtx(t)=−[ddem_gain(t)/dem_gain(t)]*Gtx gives:

$$dEM ( t ) = - dem\_mag ( t ) * dem\_gain ( t ) * Grx * dGtx ( t ) \\ = dem\_mag ( t ) * Grx * Gtx * ddem\_gain ( t )$$

So in order to compensate the transmit variations, the demand gain signal has to be changed by:

ddem_gain(t)=dEM(t)/[dem_mag(t)*Gtx(t)*Grx]

The inverse function unit 807 calculates the product of the demand magnitude signal and the gain of the transmit and receive paths. The inverse function unit 807 can for example be implemented using a programmable look-up table.

The obtained result of the inverse function unit 807 is multiplied with the difference signal EM(t) by the multiplier 808. The output of the multiplier 808 which is the desired demand gain change ddem_gain(t) is added to the current value of the demand gain signal dem_gain by the adder unit 809. The result is the next value for the demand gain and is stored in the demand gain register of the demand gain function 810.

The pulse start detect function unit 801 examines the generated demand magnitude samples and generates a start signal when it is in the inactive state and a non-zero sample is detected. It returns to the inactive state when a fixed or programmable consecutive number of zero demand magnitude samples are detected.

The start signal produced by the pulse start detect function unit 801 is applied to the delay clock unit 803 and the demand gain function unit 810. This starts the delay clock unit 803 and initializes the demand gain signal of the demand gain function unit 810 to a programmable start value. This can be used to guarantee that generated RF pulses always start with an undershoot which is more desirable than an overshoot.

It shall be mentioned, that the above control function can of course be implemented in other manners as well like for example by using a digital signal processor.

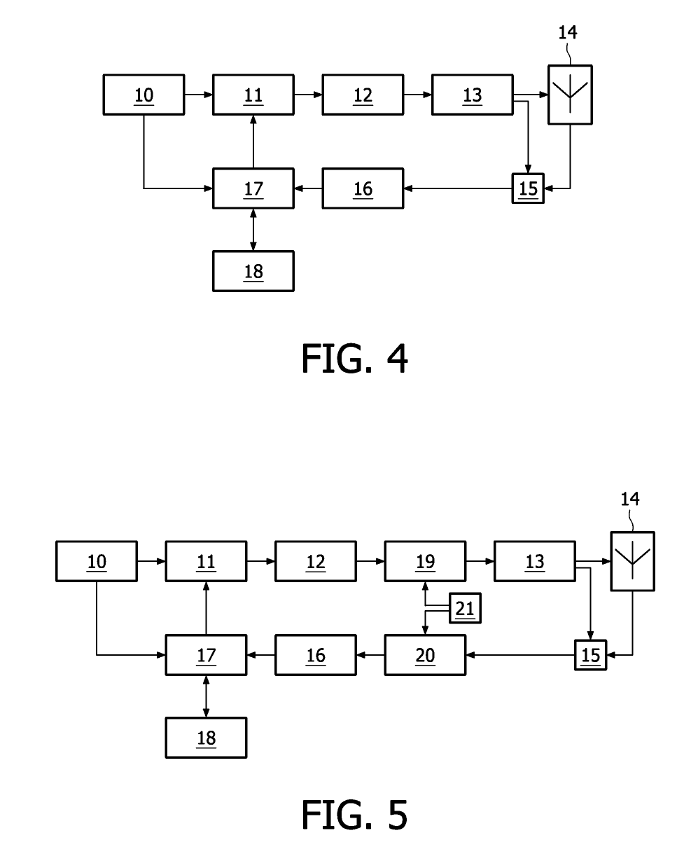

FIG. 4 shows a functional block diagram of an RF transmit system according to a second embodiment of the invention in the form of a one-channel RF transmit system. A multi-channel RF transmit system can be realized by a plurality of such channels. The RF transmit system comprises an RF waveform generator 10 for generating in the digital domain a demand RF signal, which is fed to a complex gain predistorter 11 and an adaption unit 17. An output of the complex gain predistorter 11 is connected with an input of a digital-to-analog converter 12 for converting the input signal into the analog domain. The analog output signal is then fed via an RF power amplifier 13 to an RF transmitter 14, which for example comprises an RF coil.

The RF transmit signal is sensed by means of a sensor for example in the form of a small coil which is positioned at the RF transmitter 14 and/or at the output of the power amplifier 13. One of these sensor signals (schematically indicated by a combination of the sensor signals with a logical OR gate 15) is fed to an analog-to-digital converter 16 and then supplied in the digital domain to the adaption unit 17 which controls the complex gain predistorter 11. A look-up table unit 18 is as well provided which is connected with the adaption unit 17.

By this RF transmit system, especially non-linearities of the RF components in the transmit channel and mutual coupling effects between two or more of those transmit channels can be compensated actively and automatically in the digital domain by means of the closed loop digital pre-compensation of the demand RF waveform, so that the obtained complex analog RF transmit signals have a good correlation to the demand RF waveform signals generated by the RF waveform generator 10.

Generally, this is realized by providing the digital feedback path, in which the adaption unit 17 calculates from the demand RF signal generated by the RF waveform generator 10 and the actually detected fed back RF transmit signals the resulting difference or error. This difference or error is used to pre-compensate (pre-emphasis) the demand RF signal (which had been calculated e.g. by means of RF shimming or Transmit SENSE methods) to minimize the error or difference between the actual and the demand waveform.

Also, deviations of the actual from the demand waveform that are caused by motion of the patient, such as due to breathing are automatically accounted for. Thus, the need to include this motion in the safety margin is not needed and narrow safely margins can be used, while inadvertent interruptions of the scan are avoided. These narrow safety margins reflect that overestimation of SAR is reduced because patient motion is taken into account.

More in detail, the complex gain predistorter 11 adjusts the amplitude and phase (or frequency) of each input RF demand signal from the RF waveform generator 10 in such a way that any unwanted effects are compensated as explained above. The information concerning the amount of change or adjustment of the demand RF signal is controlled by a look-up table stored in the look-up table unit 18 wherein the look-up table is constantly updated by the adaption unit 17. The values of the look-up table are preferably updated in such a way that the resulting difference between the demand RF signal and the detected RF transmit or output signal is minimized.

It is preferred to use a look-up table because usually the adaption unit 17 cannot be realized fast enough to calculate the required correction in real time. Consequently, the look-up table provides a decoupling between the demand RF signal and the correction signal. The look-up table contains the information that translates or interpolates the amplitude and phase (or frequency) modulation to account for the non-linearities of the transmit channel or couplings between different transmit channels.

The corrected (i.e. pre-distorted) digital signal at the output of the complex gain predistorter 11 is converted by means of the digital-to-analog converter 12 using direct conversion techniques into the analog domain. In case of an MRI system, the digital-to-analog converter 12 needs to be capable of supplying the Larmor frequency of the required field strength, for example 128 MHz for a 3T system.

The pre-distorted analog signal is then amplified by the RF power amplifier 13 prior to being sent to the RF transmitter 14, which is for example an MR antenna or coil.

The analog-to-digital converter 16, which uses a direct conversion technique digitizes a small part of the actual RF transmit signal of the RF amplifier 13, and the adaptation unit 17 calculates the error between the demand and actual signal. As mentioned above, the actual signal can be measured by taking a small part of the output signal of the power amplifier 13 or by using selectively coupling current or RF field sensors at each RF transmitter 14 e.g. in the form of an RF coil.

The aim is to minimize this delta/error signal. It is worth mentioning that the adaptation process uses a delayed version of the actual RF signal (output signal), as well as the delayed input sampled. However, when using an appropriately high update rate of the analog-to-digital converter 16 this delay can be neglected and must not lead to any instabilities. As the demand RF waveform and the sampled output signal will probably have different time resolutions, the input signal will be (linearly) interpolated.

FIG. 5 shows a functional block diagram of an RF transmit system according to a third embodiment of the invention, again in the form of a one-channel RF transmit system. A multi-channel RF transmit system can again be realized by a plurality of such channels.

The same or corresponding components as indicated in FIG. 4 are denoted with the same reference numerals.

This RF transmit system again comprises an RF waveform generator 10 for generating a demand RF transmit signal in the digital domain, which is fed to a complex gain predistorter 11 and to an adaption unit 17. The output of the complex gain predistorter 11 is connected with an input of a digital-to-analog converter 12 for converting the input signal into the analog domain. The output of the digital-to-analog converter 12 is connected with the input of a quadrature modulator 19, the output signal of which is fed via an RF power amplifier 13 to an RF transmitter 14 e.g. in the form of an RF coil.

The RF transmit signal is again sensed by means of a sensor for example in the form of a small coil which is positioned at the RF transmitter 14 and/or at the output of the power amplifier 13. One of these sensor signals (schematically indicated by a combination of the sensors signals with a logical OR gate 15) is fed to a quadrature demodulator 20, the output of which is connected with the input of an analog-to-digital converter 16. The quadrature modulator 19 and the quadrature demodulator 20 are both connected with a local oscillator 21.

The digital output signal of the analog-to-digital converter 16 is supplied in the digital domain to the adaption unit 17, which again controls the complex gain predistorter 11 by means of a look-up table unit 18 as explained above.

With this third embodiment, the same method as according to the second embodiment is conducted, however, using demodulation techniques. In this case the digital-to-analog converter 12 produces an analog signal (adjusted demand RF signal) close to the base band (at least away from the desired higher Larmor frequency) and the quadrature modulator 19 mixes up this signal to the desired higher frequency of the RF transmit signal. The same applies during digitization, in which by means of the quadrature demodulator 20 the detected RF transmit signal is mixed down prior to digitization into a base band or a frequency band which the analog-to-digital converter 16 can handle appropriately.

For field strength (e.g. 7T), where the direct conversion technique according to the second embodiment and FIG. 4 cannot be applied directly due to the lack of appropriate components for the digital-to-analog converter 12, this converter 12 may deliver a signal different from the base band (e.g. 128 MHz) and then the quadrature modulator 19 mixes up the frequency of the signal to the desired Larmor frequency.

This invention is applicable to any MRI system with single or multi-channel RF transmit capability and is of particular interest at high field strengths. In combination with e.g. the compensation of wave propagation effects (sometimes also called dielectric resonances), which result in inhomogeneous images it is possible to use new methods like Transmit SENSE to overcome this problem. It is thus a crucial element in the design of these multi-channel RF transmit systems. Furthermore, new methods like Transmit SENSE will enable new applications for MRI systems. Nevertheless, for the use of the multiple Tx channels, the accurate and independent control of the RF signals according to the invention has considerable advantages.

While the invention has been illustrated and described in detail in the drawings and foregoing description, such illustration and description are to be considered illustrative or exemplary and not restrictive, and the invention is not limited to the disclosed embodiments. Variations to embodiments of the invention described in the foregoing are possible without departing from the scope of the invention as defined by the accompanying claims.

Variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope.

1. A method for generating RF transmit signals by means of an RF transmit system for feeding an RF transmitter, comprising the following steps:
detecting an RF transmit signal which is generated at an output of the RF transmit system or at the RF transmitter,
converting the detected RF transmit signal into a digital signal,
evaluating a difference or error between the digitized detected RF transmit signal and a demand RF signal which is supplied to the RF transmit system or generated by the RF transmit system,
digitally adjusting the demand RF signal such that the difference or error is at least minimized or removed such that the RF transmit signal is at least substantially equal to or corresponds or correlates with the demand signal.

2. The method according to claim 1, wherein the difference or error between the digitized detected RF transmit signal and the demand RF signal is evaluated in the form of at least one of: the level stability of the signals, the linearity of the signals, the dynamic range of the signals, the amplitudes of the signals, the phases of the signals.

3. An RF transmit system for generating RF transmit signals according to claim 1, comprising a sensor for detecting an RF transmit signal which is generated at the output of the RF transmit system or at the RF transmitter, a digital-to-analog converter for converting the detected RF transmit signal into the digital domain, an adaption unit for calculating in the digital domain from a demand RF signal generated by an RF waveform generator and the detected RF transmit signal a resulting difference or error, and a complex gain predistorter for digitally adjusting the demand RF signal on the basis of the calculated difference or error such that this difference or error is at least minimized or removed.

4. The RF transmit system according to claims 3, in which a look-up table unit is provided for storing a look-up table for controlling the amount of adjustment of the demand RF signal in dependence on the difference or error calculated by the adaption unit.

5. The RF transmit system according to claim 4, wherein the adaption unit is provided for updating the look-up table stored in the look-up table unit in such a way that the calculated difference or error between the demand RF signal and the RF transmit signal is at least minimized or removed.

6. The RF transmit system according to claim 3, comprising a quadrature modulator for mixing up the adjusted demand RF signal to a desired higher frequency of the RF transmit signal, and a quadrature demodulator for mixing down the detected RF transmit signal to a desired lower frequency prior to digitalization by means of the digital-to-analog converter.

7. The RF transmit system for generating RF transmit signals according to claim 1, comprising an RF power amplifier for feeding an RF transmitter with an RF signal, an activation circuit to provide an input signal to the RF power amplifier, and a control circuit for controlling the activation circuit, wherein the control circuit is provided for sampling the output signal of the RF power amplifier or of the RF transmitter, for digitally comparing the measured output signal with a demand signal and for digitally correcting the input signal to the RF power amplifier.

8. The RF transmit system according to claim 7, wherein the control circuit is provided with a feed-forward function for pre-setting the activation circuit on the basis of a selected MR acquisition sequence.

9. A magnetic resonance imaging system comprising at least one RF transmit system according to claim 3.

10. A computer program comprising a computer program code adapted to perform a method or for use in a method according to claim 1 when said program is run on a programmable microcomputer.
